(19) United States
(12) Patent Application Publication
(10) Pub. No.: US 2007/0228385 A1
(43) Pub. Date: Oct. 4, 2007

(54) Edge-emitting light emitting diodes and methods of making the same

(75) Inventors: XianAn Cao, New Paltz, NY (US); Steven Francis Leboeuf, Schenectady, NY (US); Alexei Vertiatchikh, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/396,027

(22) Filed: Apr. 3, 2006

(51) Int. Cl. H01L 33/00

(52) U.S. Cl. 257/79

(57) ABSTRACT

An edge-emitting light emitting diode (EELED) and methods are described. The EELED includes contact layer, a first carrier confinement layer coupled to the contact layer, an active region optically coupled to the first carrier confinement layer. The active region includes an aluminum gallium nitride based material. Further, the EELED includes a second carrier confinement layer coupled to the active region.

### STATEMENT REGARDING FEDERALLY SPONSORED RESEARCH AND DEVELOPMENT

This invention was made with Government support under contract number W91CRB-04-C-0063 awarded by DARPA. The government has certain rights in the invention.

### BACKGROUND

The invention relates generally to the field of light emitting diodes. More particularly, the invention relates to edge-emitting light emitting diodes and methods of making the same.

Conventional light emitting diodes (LEDs) emit light from the surface of the LED. Large emitting areas lead to large divergence angles, low radiance, and low coupling efficiencies to optical fibers. Accordingly, complex optical systems have been required to obtain focused high-flux beams.

Generally, edge-emitting light emitting diodes (EELEDs) are employed to address one or more of the above mentioned concerns. Typically, the structure of a conventional EELED includes an active layer, which is surrounded by two confining layers. The confining layers in turn are surrounded by two optical guide layers, which form an optical waveguide The light is emitted from the side of the EELED after multiple internal reflections at the interface between a confining layer and an optical guide layer. The waveguide vastly reduces the divergence of the emitted light beams.

Occasionally, laser diodes (LDs) are employed as EELED alternatives for achieving high radiance and efficient coupling. However, LDs are not stable over wide operating temperature ranges and require more elaborate circuitry to achieve acceptable stability. Also, typically, LDs with emission wavelengths in the ultraviolet (UV) regime are difficult and expensive to grow and fabricate.

EELEDs typically operate at high current densities, and may have a higher quantum efficiency than conventional surface emitting LEDs. However, the light generated in the active layer typically experiences multiple internal reflections at the interfaces of the waveguide before escaping from the LED structure. Due to the re-absorption of light within the active layer, the total optical power output of an EELED may be a fraction of that from a comparable surface-emitter LED.

There exists a need for a suitable short-wavelength EELED, which has high-radiance for biological and chemical sensing, and a high optical coupling efficiency for integration of the EELED with other optical and electronic devices.

### BRIEF DESCRIPTION OF THE DRAWINGS

FIGS. 1-4 are cross-sectional views of edge-emitting light emitting diodes in accordance with exemplary embodiments of the invention.

FIG. 5 is a cross-sectional view of an edge-emitting light emitting diode emitting radiation from the edges in accordance with an exemplary embodiment of the invention.

FIG. 6 is a diagrammatical illustration of the emission pattern of the edge-emitting light emitting diode in accordance with an exemplary embodiment of the invention.

FIG. 7 is a cross-sectional view of a laterally-structured edge-emitting light emitting diode device illustrating positioning of a second electrode in accordance with an exemplary embodiment of the invention.

FIG. 8 is a cross-sectional view of a vertically-structured edge-emitting light emitting diode device in accordance with an exemplary embodiment of the invention.

FIG. 9 is a cross-sectional view of a laterally-structured edge-emitting light emitting diode device illustrating positioning of a second electrode in accordance with exemplary embodiments of the invention.

FIG. 10 is a diagrammatical illustration of a hybrid integration of an edge-emitting light emitting diode with aluminum gallium nitride based detectors in accordance with an exemplary embodiment of the invention.

FIG. 11 is a diagrammatical illustration of a monolithic integration of an edge-emitting light emitting diode and a nitride-based photodetector in accordance with an exemplary embodiment of the invention.

### SUMMARY

Embodiments of the invention are directed to a system and methods for making an edge-emitting light emitting diode.

One exemplary embodiment of the invention is an edge-emitting light emitting diode. The edge-emitting light emitting diode includes a contact layer, a first carrier confinement layer coupled to the contact layer, an active region optically coupled to the first carrier confinement layer. The active region includes an aluminum gallium nitride based material. Further, the edge-emitting light emitting diode includes a second carrier confinement layer optically coupled to the active region.

Another exemplary embodiment of the invention is an edge-emitting light emitting diode. The diode includes a contact layer, a first carrier confinement layer coupled to the contact layer, where the carrier confinement layer includes an aluminum gallium nitride based material. Further, the edge-emitting light emitting diode includes an active region optically coupled to the first carrier confinement layer, the active region having an aluminum gallium nitride based material or an indium gallium nitride based material. The edge-emitting light emitting diode further includes a second carrier confinement layer optically coupled to the active region, where the second carrier confinement layer includes an aluminum gallium nitride based material, and where the second carrier confinement layer is n-doped. The edge-emitting light emitting diode further includes a cladding layer optically coupled to the second carrier confinement layer, where the cladding layer includes an aluminum gallium nitride based material, and where the cladding layer is either n-doped or undoped. Further, the edge-emitting light emitting diode includes a buffer layer coupled to the cladding layer and a substrate coupled to the buffer layer.

Another exemplary embodiment of the invention is a system having an edge-emitting light emitting diode of the present invention. The system further includes an electronic device optically coupled to the diode and configured to detect radiation from the edge-emitting light emitting diode.

These and other advantages and features will be more readily understood from the following detailed description of preferred embodiments of the invention that is provided in connection with the accompanying drawings.

### DETAILED DESCRIPTION OF EXEMPLARY EMBODIMENTS

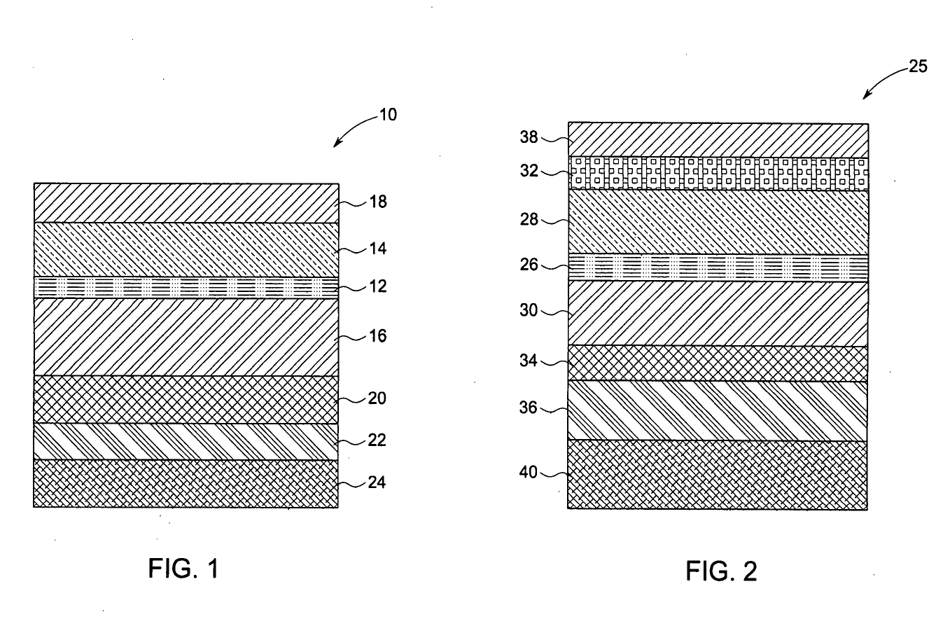

Embodiments of the invention relate to structures of edge-emitting light emitting diodes (EELEDs). As used herein, the term “edge-emitting light emitting diode” refers to a light emitting diode (LED) that is configured to emit light through one side of the LED as opposed to emitting light from the surface of the LED. As will be explained with reference to FIGS. 1-4 and 7-9, the EELED structures include an active region having an aluminum gallium nitride based material. Group III nitrides are desirable candidates for ultraviolet EELEDs. The material of the active region may absorb optical energy produced by the recombination of charge carriers. Therefore, the active region is usually constructed so that it is relatively thin (less than about 0.1 micrometers) to increase the optical efficiency of the EELED. The active region is disposed between and optically coupled to first and second carrier confinement layers. In one embodiment, the first carrier confinement layer is coupled to a contact layer, and the second carrier confinement layer is coupled to a buffer layer.

As used herein, the term “coupled” may refer to direct or indirect coupling. For example, the phrase “the first carrier confinement layer coupled to the contact layer” also includes the embodiments where there is an additional layer disposed between the first carrier confinement layer and the contact layer.

Typically, electric current is injected into the EELED through the electrodes to generate electron and holes in the active region. These electrons and holes then recombine to produce light, which is emitted out of the EELED through the edges of the active region. In certain embodiments, the active region may include one or more quantum wells.

The first and second carrier confinement layers are configured to prevent the charge carriers injected into the active region from going out of the active region. In other words, the first and second carrier confinement layers confine the charge carriers in the active region to facilitate recombination of charge carriers, thereby facilitating the generation of light from the EELED. In embodiments of the invention, the carrier confinement layers may include an aluminum gallium nitride based material. The compositions of the aluminum gallium nitride based materials in the first and second carrier confinement layers are different from the composition of the aluminum gallium nitride based material of the active region. It should be appreciated, that this change in the composition of the material of the active region and the two carrier confinement layers facilitates differentiation between the optical properties, such as refractive index, of these regions. Further, the compositions of the first and second carrier confinement layers may be different from each other. Additionally, the first and second carrier confinement layers are doped. In one embodiment, the first and second carrier confinement layers are p-type and n-type doped, respectively. The thickness of the carrier confinement layers is chosen such that the light generated in the active region leaves the EELED device either without reflection or after a limited number of reflections. Thereby, allowing the light generated in the active region to leave the device after passing through a small distance in the energy absorbing material of the active region thus resulting in a high efficiency device. As used herein, the term “EELED device” refers to a structure having an EELED coupled to first and second electrodes. As will be described in detail below, in addition to the first and second electrodes the EELED device may include a dielectric passivation layer, a reflective coating and an anti-reflective coating.

The EELED may include a substrate coupled to a buffer layer. The substrate may be either electrically conducting or electrically insulating. Examples of an electrically conducting substrate may include, but are not limited to, silicon carbide, silicon, and gallium nitride. Whereas, non-limiting examples of electrically insulating substrates may include sapphire, and aluminum nitride. Additionally, the substrate may include other materials such as zinc oxide, zinc magnesium oxide, zinc manganese oxide, lithium gallate, zirconia, boron nitride, or combinations thereof. The buffer layer may be used as a stress relief layer between the substrate and the EELED structure. For example, in case of lattice mismatch between the substrate and the second carrier confinement layer, a buffer layer may be employed such that the buffer layer provides lattice match at the substrate-buffer layer interface and also at the second carrier confinement layer-buffer layer interface. The buffer layer may comprise a single or a multi-layer structure, such as a graded aluminum gallium nitride structure, and a aluminum gallium nitride superlattice structure.

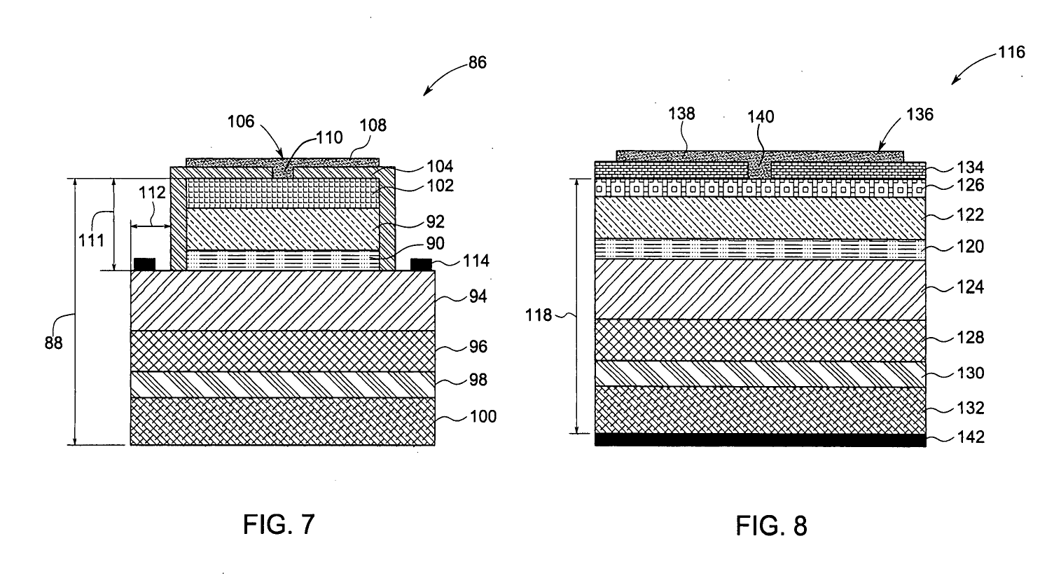

Further, two electrodes, in electrical communication with each other, may be coupled to the regions of the EELED to form an EELED device. The first electrode, with a stripe geometry, for example, is coupled to the contact layer. As will be described in detail below with regard to FIGS. 7-10, the second electrode may be positioned at different locations on the regions of the EELED depending upon the desirable properties, and the nature of the substrate. For example, for a vertical device employing a conducting substrate, such as silicon carbide or gallium nitride, the second electrode may be coupled vertically opposite to the first electrode. In this embodiment, the second electrode may be coupled to the side of the substrate which is opposite to the side that is coupled to the EELED. In other example, while employing an insulating substrate, such as sapphire, aluminum nitride, in the EELED, the second electrode may be coupled to a portion of the second carrier confinement layer.

Optionally, the EELED may also include two cladding layers disposed between the contact layer and the buffer layer. The cladding layers are employed to form a waveguiding region to guide the light emitted from the active region, out of the EELED. For example, the EELED may include a first cladding layer disposed between the second carrier confinement layer and the buffer layer, and the second cladding layer disposed between the first carrier confinement layer and the contact layer. In some embodiments, the cladding layers may be disposed in the first or second carrier confinement layers. In these embodiments, the cladding layers may either be defined by one or more boundaries of the carrier confinement layer or may be inserted inside the carrier confinement layer. The cladding layers may include an aluminum gallium nitride based material.

In some embodiments, only one cladding layer is employed in the EELED. The cladding layer is disposed between the second carrier confinement layer and the buffer layer. The first carrier confinement layer is configured to act as a cladding layer in addition to acting as a carrier confinement layer. In these embodiments, the first carrier confinement layer is directly coupled to the contact layer. Further, in these embodiments, the carrier confinement layer may be grown thicker for effective optical confinement. In other embodiments, no additional cladding layers may be employed. The first electrode is employed as the first cladding layer, and the substrate or buffer layer is used as the second cladding layer.

In embodiments of the invention, the refractive index of the cladding layers is lower than a refractive index of adjacent regions, thereby directing the light through the waveguiding region. For example, the refractive index of the first cladding layer, which is disposed between the contact layer and the first confinement layer may be lower than the refractive index of the adjacent regions, that is, the first confinement layer, and the active region. Similarly, the refractive index of the second cladding layer may be lower than the refractive index the carrier confinement layer. Such a structure functions as reflectors guiding light to travel within the waveguiding region and leave the LED at the ends of the waveguiding structure. Typically, the light may be made to come out from one end of the waveguiding structure. This may be achieved by cleaving and applying a reflective coating at the non-emitting end and an anti-reflective coating at the emitting end.

It should be appreciated that the higher amount of aluminum in an aluminum gallium nitride layer lowers the refractive index of the layer. Therefore, it is desirable to have high aluminum content in the cladding layers. However, growing an aluminum nitride layer having high aluminum content is relatively difficult due to process constraints. In embodiments of the invention, the cladding layers may include a superlattice structure. As used herein, the term “superlattice structure” refers to a stack of plurality of crystal layers having varying thickness and material composition. In this stack the plurality of crystal layers are arranged in a periodic order of the thickness and the material composition. In one embodiment, the plurality of crystal layers of aluminum gallium nitride based material have alternating high and low concentration of aluminum. It should be appreciated that such an arrangement of the plurality of crystal layers in the superlattice structure facilitates dislocation filtering, and strain management, while enabling low refractive index due to high aluminum content.

The superlattice structure enables high content of aluminum in the waveguiding region as opposed to a cladding layer made of a single layer. Additionally, the cladding layer having superlattice structure may be grown thicker without increasing the strains produced by transfer of defects, such as dislocations, from an underlying layer through the thickness of the superlattice structure because in case of superlattice structure the defects from the underlying layer may not get transferred to the successive layer due to change of properties, such as material composition, of the crystal layers. Further, the superlattice structures also facilitate doping enhancement due to piezoelectric effects, and carrier confinement due to high amount of aluminum. The superlattice structure may be formed by growth techniques such as, metal-organic chemical vapor deposition, or molecular beam epitaxy.

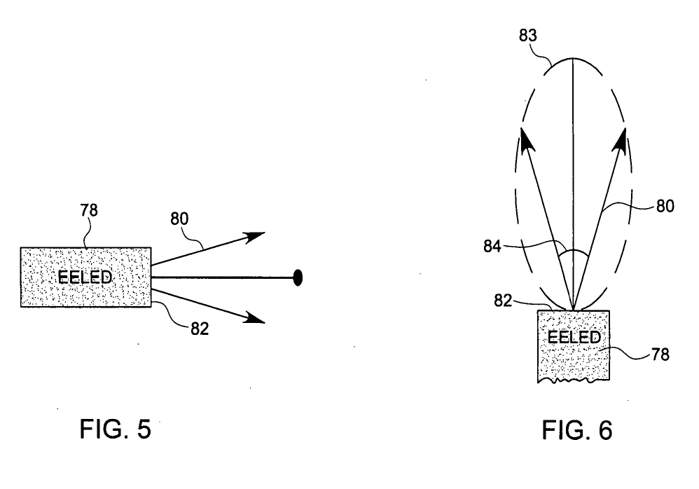

As will be described in detail below with respect to FIGS. 5 and 6, the edge-emitting property of the EELED contributes to small divergence of the emitted light, and the structure of the diode, including the stripe-shaped electrode, the active region, the carrier confinement layers, the cladding layers, results in a small emitting area and low losses of the emitted light, thereby resulting in high radiance. In some embodiments, the light emitted from the EELED may be in a UV region. In an exemplary embodiment, the light emitted from EELEDs with an aluminum gallium nitride active region may be in a deep UV region, that is, the light emitted by the EELED may be in a range from about 220 nanometers to about 370 nanometers. Whereas, in other embodiments, the light emitted by EELEDs with an indium gallium nitride active region may be in a visible range. For example, the light emitted from the EELED may be in a range of from about 370 nanometers to about 780 nanometers.

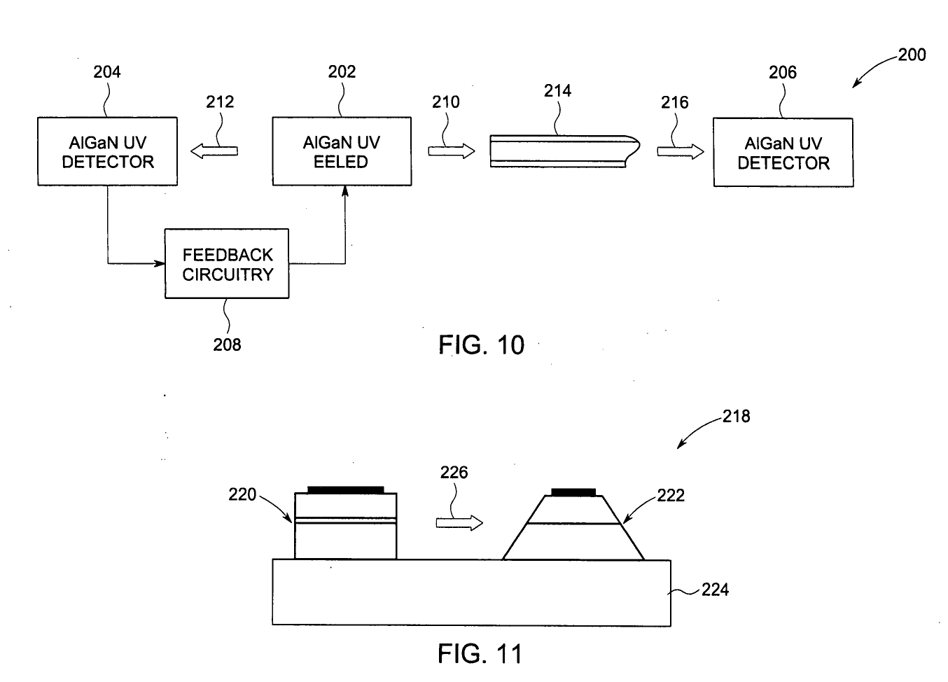

Further, as will be described in detail below with regard to FIGS. 10 and 11, the EELED may be placed in operative association with other electronic devices. The operative association between the EELED and the electronic device may be achieved by placing or growing the EELED and the electronic devices on the same substrate such that the electronic device may receive the light emitted from the EELED. The electronic device and the EELED may be positioned at a small distance to maintain direct optical coupling between the two devices. Alternatively, the electronic device may be optically coupled to the EELED through an optically active media, such as an optical fiber. Also, it should be appreciated that by employing EELED rather than surface emitting LEDs more power may be coupled to the optical fiber due to the small light emitting surfaces and small divergence angle.

Referring now to FIG. 1, an EELED 10 is illustrated. In the illustrated embodiment, the EELED 10 includes an active region 12 disposed between first and second carrier confinement layers 14 and 16 and including quantum wells. Additionally, a cladding layer 20 is positioned between the second carrier confinement layer 16 and a buffer layer 22. In the FIG. 1 embodiment, the first carrier confinement layer 14 is configured to act as a cladding layer in addition to confining the free charge carriers in the active region 12. The thickness of the carrier confinement layer 14 is relatively large, to ensure effective carrier as well as photon confinement. In one embodiment, the thickness of the carrier confinement layer 14 is in the range of from about 0.01 micrometers to about 1 micron.

The buffer layer 22 is coupled to a substrate 24. As discussed above, the buffer layer 22 acts as a stress-relief layer between the second waveguiding region 20 and the substrate 24, thereby avoiding any strains due to lattice mismatch between the substrate 24 and the region 20. The EELED 10 further includes a contact layer 18, where the contact layer 18 is used to deposit metal contacts for an electrode (not shown) to form an EELED device. As described in detail below with regard to FIGS. 7-9, the portion of the electrode that contacts the contact layer 18 is in the form of a strip having a width of less than about 100 micrometers. The narrow area of contact between the electrode and the contact layer restricts the injected current to corresponding narrow regions of the subsequent regions. When the electric current is injected along this narrow strip of the electrode, the current flow is restricted to only this narrow region in the subsequent regions, thereby resulting in a small light emitting portion.

In the illustrated embodiment, the active region 12 includes aluminum gallium nitride having the composition of AlₓGa₁₋ₓN and Al_{y}Ga_{1-y}N to form the quantum wells, where x and y represent the molar fractions of aluminum in the composition. Likewise, carrier confinement layer 14 may include an aluminum gallium nitride based material having the composition of AlₘGa₁₋ₘN, where m is the molar fraction. Similarly, the cladding layer 20 may be made of aluminum gallium nitride having the composition Al_{z}Ga_{1-z}N, where z is the molar fraction. Further, the contact layer 18 may include gallium nitride or indium gallium nitride. In these embodiments, the molar fractions x and y of the active region 12 are less than the molar fractions m or z of the regions 14 and 20. In other words, the aluminum content of the active region 12 is lower than the aluminum content of the surrounding regions, thereby resulting in a lower refractive index of the surrounding regions relative to the active region. For example, the refractive index of the cladding layers is smaller than the refractive index of the active region and the second carrier confinement layer. As discussed above, such a difference in the refractive indices prevents the light emitted from the active region from going out through the surface. That is, the region confined between the two cladding layers acts as a waveguide, with the active region being the core of the waveguide. Also, the thickness of the waveguide, that is, the thickness of the regions between the cladding layers 14 and 20 is about one fourth or greater than the wavelength of the emitted light.

Additionally, the regions 14, 16, 18 and/or 20 may be doped. In one embodiment, the contact layer 18, and the first carrier confinement layer 14 is p-doped, whereas the second carrier confinement layer 16 and the second cladding layer 20 are n-doped. When the p-n junction is forward biased, injected charge carriers (electrons and holes) recombine in the active region 12 and light is generated. The light is emitted from an edge of the device, such as the edge of the waveguiding region, along a path which is parallel to the plane of the p-n junction. As will be described below with regard to FIGS. 11 and 12, an optical fiber may be aligned with this path at the edge of the EELED 10 where the light is emitted. Although not illustrated, an antireflective coating may be deposited at the emitting end, and a reflective coating may be deposited at the opposite end of the EELED 10.

Processes such as liquid phase epitaxy (LPE), vapor phase epitaxy (VPE), such as molecular beam epitaxy (MBE), or metal-organic chemical vapor deposition (MOCVD), may be applied to deposit the different regions of the EELED 10. The thickness of these regions may vary from about 2 nanometers to about 5 micrometers. For example, the active region 12 may have a thickness in a range of from about 2 nanometers to about 200 nanometers. Whereas, first and second carrier confinement layers 14 and 16 may have relatively higher values of thickness to effectively spread current and confine the charge carriers in the active region 12 for recombination. For example, second carrier confinement layer 14 and 16, each may have a thickness in a range of from about 0.1 micrometers to about 5 micrometers. The cladding layers may have relatively higher values of thickness of the order of a few micrometers.

Turning now to FIG. 2, an EELED 25 is illustrated. The EELED 25 includes an active region 26 sandwiched between first and second carrier confinement layers 28 and 30. The active region 26 may be made of aluminum gallium nitride and includes quantum wells. The first and second carrier confinement layers also may include aluminum gallium nitride. As in FIG. 1, the aluminum content in the first and second carrier confinement layers 28 and 30 is relatively more than that in the active region 26. Also, the first and second carrier confinement layers 28 and 30 may be p-doped and n-doped, respectively. The EELED 25 further includes first and second cladding layers 32 and 34 coupled to the first and second carrier confinement layers 28 and 30, respectively. The first and second cladding layers 32 and 34 may be made of aluminum gallium nitride, and may be p-doped and n-doped, respectively. As described above with respect to FIG. 1, the aluminum content in the layers 26, 28 and 30 is lower than the aluminum content in the first and second waveguiding regions 32 and 34. Further, the EELED 25 includes a contact layer 38 disposed on the first cladding layer 32. The EELED 25 further includes a buffer layer 36 coupled to the second cladding layer 34 on one side and disposed on a substrate 40 on the other side. The buffer layer 36 is formulated to facilitate epitaxial growth of subsequent regions, such as cladding layers, carrier confinement layers, and active regions, while reducing defect propagation from the underlying substrate 40 into these regions.

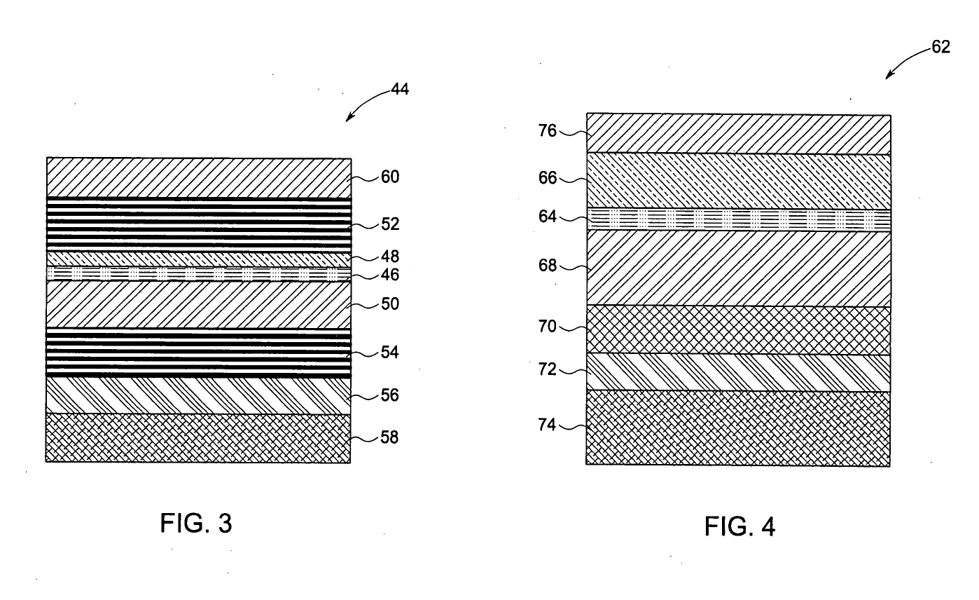

FIG. 3 illustrates another EELED 44. The EELED 44 employs an active region 46 sandwiched between the first and second carrier confinement layers 48 and 50. The first and second carrier confinement layers 48 and 50 are coupled to first and second cladding layers 52 and 54, respectively. In the illustrated embodiment, both the first and second cladding layers 52 and 54 include superlattice structures. The superlattice structures of the regions 52 and 54 may include aluminum gallium nitride crystal layers. The thickness of the superlattice structures is in a range of from about 0.01 micrometers to about 1 micrometer. The thickness of the cladding layers 52 and 54 may be in a range of from about 0.01 micrometers to about 5 micrometers. Further, the second cladding layer 54 may be coupled to a buffer layer 56 and a substrate 58. The EELED 44 further includes a contact layer 60 disposed on the first cladding layer 52.

FIG. 4 illustrates an EELED 62 having an active region 64, which may be made of indium gallium nitride or gallium nitride. The active region 64 is sandwiched between the first and second carrier confinement layers 66 and 68. As with the first carrier confinement layer 14 of FIG. 1, the first carrier confinement layer 66 is configured to serve also as a cladding layer. The first carrier confinement layer 66 may be p-doped and may include an aluminum gallium nitride layer or aluminum gallium nitride superlattice layer, whereas the second confinement layer 68 may be n-doped and may be made of aluminum gallium nitride. The EELED 62 further includes a cladding layer 70 that may include an aluminum gallium nitride layer or aluminum gallium nitride superlattice layer. The cladding layer 70 may be either n-doped or un-doped. The EELED 62 further includes a p-doped contact layer 76 that may be made of gallium nitride or indium gallium nitride. In this embodiment, the EELED 62 emits light in the visible region. For example, the emitted light may be in a range of from about 370 nanometers to about 780 nanometers.

FIG. 5 illustrates an EELED 78 emitting radiation 80 through the side 82. The EELED 78 may be replaced by any of the EELEDs 10, 25, 44 or 62 of the illustrated embodiments of FIGS. 1, 2, 3 or 4, respectively. FIG. 6 illustrates the emission pattern 83 from the edge 82 of the EELED 78. Due to the edge emittance property, the emergence angle 84 of the radiation 80 is relatively smaller than that of a conventional surface-emitting LED.

Referring to FIGS. 7-9, alternate embodiments of devices employing EELEDs are illustrated. The depicted device embodiments are suitable for the earlier illustrated EELED diodes described above with regard to FIGS. 1-4.

FIG. 7 illustrates an EELED device 86 employing a laterally-structured EELED 88 having a structure grown on an insulating substrate such as sapphire and aluminum nitride. As used herein, the term “laterally-structured EELED” refers to the EELED having the first and second electrodes disposed on the same side of the substrate as will be described in detail below. In the illustrated embodiment, the EELED 88 includes an active region 90, first and second carrier confinement layers 92 and 94, a cladding layer 96, a buffer layer 98 and a substrate 100. The substrate 100 includes an insulating material. Due to the insulating nature of the substrate 100, a mesa 111 is defined using plasma etching to expose a portion 112 of the second carrier confinement layer 94 for metal contact. The mesa 111 is formed by etching away portions of the layers 90, 92 and 102. A dielectric passivation layer 104 is disposed on a contact layer 102 and patterned to provide an opening for a protruding stripe-shaped portion 110 of a first electrode 106. The first electrode 106 includes a continuous portion 108, which is disposed on the dielectric passivation layer 104. The width of the opening 110 is in the range of 5 micrometers to about 100 micrometers. In addition, the dielectric passivation layer 104 may also cover the mesa sidewall. The device 86 also includes second electrodes 114 in electrical communication with the first electrode 106 and disposed around the mesa 111, on an exposed portion 112 of the second carrier confinement layer 94. Although not illustrated, the device 86 may further include an antireflective coating disposed on the side wall of the mesa 111 of the emitting end and a reflective coating disposed on the sidewall of the mesa 111 of the non-emitting end of the EELED 88.

FIG. 8 illustrates an EELED device 116 employing a vertically structured EELED 118, which includes a structure similar to the EELEDs of FIGS. 1 and 7, grown on a conducting substrate such as gallium nitride or silicon carbide. As used herein, the term “vertically-structured EELED” refers to the EELED having the first and second electrodes disposed on the opposite sides of the substrate as will be described in detail below. Specifically, the EELED 118 includes an active region 120 disposed between first and second carrier confinement layers 122 and 124. Further, a contact layer 126 is disposed on the first carrier confinement layer 122. The EELED 118 further includes a cladding layer 128 coupled to the second carrier confinement layer 124. Further, the EELED 118 includes a buffer layer 130 and a substrate 132. Similar to the first electrode 106 of FIG. 7, the first electrode 136 includes a continuous region 138 and a protruded or stripe shaped region 140, which fits within an opening in the dielectric passivation layer 134. A second electrode 142 of the device 116 is electrically coupled to the first electrode 136 via the substrate 132.

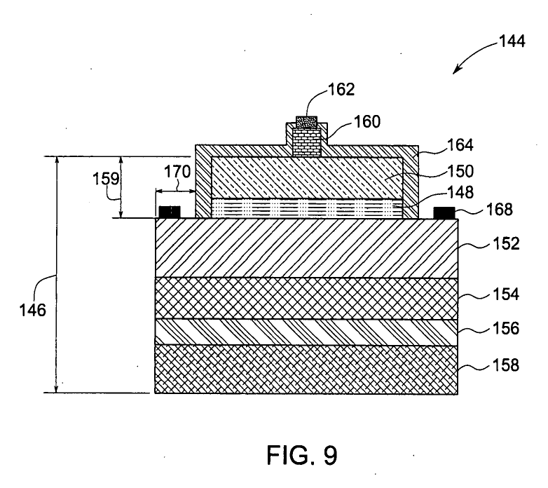

FIG. 9 illustrates an EELED device 144 having a laterally-structured EELED 146 within similar fashion as the EELED 10 of FIG. 1. The EELED 146 includes an active region 148 sandwiched between the first and second carrier confinement layers 150 and 152. The EELED 146 further includes a cladding layer 154 disposed adjacent to the second carrier confinement layer 152 and coupled to a buffer layer 156. The buffer layer 156 in turn is disposed on a substrate 158. The substrate 158 may be non-conductive. A mesa 159 is formed by partially etching the layers 148, 150 and 160 using plasma etching. The device 144 further includes a contact layer 160 disposed over the first carrier confinement layer 150. The layer 160 is further etched to form a stripe shape for improved lateral current confinement. The device 144 also includes a stripe-shaped first electrode 162 coupled to the first contact layer 160 and a second electrode 168 disposed on the second carrier confinement layer 152 and positioned around the mesa 159.

The device 144 further includes a dielectric passivation layer 164 disposed around and surrounding the exposed top and side surfaces of the contact layer 160, the first carrier confinement layer 150 and the sidewall of the mesa 159.

Turning now to FIG. 10, a hybrid integration system 200 employing an EELED 202, an aluminum gallium nitride based detector 204 and 206, and a feedback circuitry 208 is illustrated. The EELED 202 may have structures similar with those described above with regard to FIGS. 1-4 and 7-9. As illustrated, the emitted radiation 210 from one emitting end of EELED 202 is received by a device 214. The device 214 may be, for example, a biochemical sensor, a water purification device, an air purification device, a polymer curing device, a chemical processing device, a therapeutic device, a solid-state lighting device, and an optical fiber. The light 212 emitted from the other emitting end of the EELED 202 is received by the detector 204. Depending on the value of the portion 212 of the radiance, a signal is sent to the feedback circuitry 208, which in turn controls the input power to the EELED 202 to maintain the total emitted radiation of the EELED 202 at a predetermined value. Whereas, the other portion 210 of the emitted radiation is converted into radiation 216 after interaction with the samples 214 and received by the detector 206.

FIG. 11 illustrates an EELED system 218 including a monolithic integration of an EELED device 220 with an electronic device 222. The device 222 may be, for example, a photodetector, or a transistor. In an exemplary embodiment, the device 222 may be a nitride-based photodetector. As illustrated, the EELED device 220 and the electronic device 222 are disposed on the same substrate 224 and positioned such that at least a portion of the radiation 226 from the EELED device 220 is received by the electronic device 222. In such a compact system 218, the transmission of the radiation 226 from the EELED device 220 to the electronic device 222 may be possible without employing optical fibers. The system has the advantage of compact size, and may be used for biochemical sensing or a non-line-of-sight communication.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. For example, while the EELED is described in conjunction with a biochemical sensor, a water purification device, an air purification device, a polymer curing device, a chemical processing device, a therapeutic device, a solid-state lighting device, a non-line-of-sight communication device, a high-density data storage device, it should be appreciated that such EELEDs may find utility for any application in which a light emitting diode may be applied. Additionally, while various embodiments of the invention have been described, it is to be understood that aspects of the invention may include some of the described embodiments. Accordingly, the invention is not to be seen as limited by the foregoing description, but is only limited by the scope of the appended claims.

What is claimed as new and desired to be protected by Letters Patent of the United States is:

1. An edge-emitting light emitting diode, comprising:
a contact layer;
a first carrier confinement layer coupled to said contact layer;
an active region optically coupled to said first carrier confinement layer, said active region comprising an aluminum gallium nitride based material; and
a second carrier confinement layer optically coupled to said active region.

2. The edge-emitting light emitting diode of claim 1, wherein at least one of said first and second carrier confinement layers comprises an aluminum gallium nitride based material.

3. The edge-emitting light emitting diode of claim 1, further comprising a buffer layer coupled to said second carrier confinement region.

4. The edge-emitting light emitting diode of claim 3, wherein said buffer layer is a stress relief layer.

5. The edge-emitting light emitting diode of claim 3, further comprising a substrate coupled to said buffer layer.

6. The edge-emitting light emitting diode of claim 5, wherein said substrate comprises sapphire, aluminum nitride, silicon carbide, silicon, gallium nitride, zinc oxide, zinc magnesium oxide, zinc manganese oxide, lithium gallate, zirconia, boron nitride, or combinations thereof.

7. The edge-emitting light emitting diode of claim 3, further comprising at least one cladding layer disposed between said contact layer and said buffer layer for optical confinement.

8. The edge-emitting light emitting diode of claim 7, wherein said cladding layer comprises an aluminum gallium nitride based material.

9. The edge-emitting light emitting diode of claim 1, comprising first and second cladding layers forming a waveguiding region.

10. The edge-emitting light emitting diode of claim 9, wherein an aluminum concentration in said first cladding layer is more than an aluminum concentration in one or more of said active region, said first carrier confinement layer, and second carrier confinement layer.

11. The edge-emitting light emitting diode of claim 9, wherein a refractive index of said first cladding layer is lower than a refractive index of said active region and said first carrier confinement layer.

12. The edge-emitting light emitting diode of claim 9, wherein said contact layer is p-doped, said first cladding layer is p-doped, said first carrier confinement layer is p-doped, and said second carrier confinement layer is n-doped.

13. The edge-emitting light emitting diode of claim 9, wherein said first cladding layer is disposed in said first carrier confinement layer.

14. The edge-emitting light emitting diode of claim 9, wherein said first cladding layer and said second cladding layer comprises a superlattice structure.

15. The edge-emitting light emitting diode of claim 14, wherein said superlattice structure comprises a plurality of layers of aluminum gallium nitride based material.

16. The edge-emitting light emitting diode of claim 9, wherein an aluminum concentration in said second cladding layer is more than an aluminum concentration in one or more of said active region, said first carrier confinement layer, and said second carrier confinement layer.

17. The edge-emitting light emitting diode of claim 9, wherein a refractive index of said second cladding layer is lower than a refractive index of said active region and said second carrier confinement layer.

18. The edge-emitting light emitting diode of claim 9, wherein said contact layer is p-doped, said first carrier confinement layer is p-doped, said second carrier confinement layer is n-doped, and said second cladding layer is either undoped or n-doped.

19. The edge-emitting light emitting diode of claim 9, wherein said second cladding layer is disposed in said second carrier confinement layer.

20. The edge-emitting light emitting diode of claim 1, wherein said contact layer comprises a gallium nitride or indium gallium nitride based material.

21. The edge-emitting light emitting diode of claim 1, further comprising a first electrode coupled to said contact layer, and a second electrode in electrical communication with said first electrode.

22. The edge-emitting light emitting diode of claim 20, wherein said first electrode is stripe-shaped and disposed over said contact layer.

23. The edge-emitting light emitting diode of claim 20, wherein said second electrode is electrically coupled to and disposed over a portion of said second carrier confinement layer.

24. The edge-emitting light emitting diode of claim 1, further comprising a dielectric passivation layer disposed on at least a portion of one of said contact layer, said active region, said first carrier confinement layer, or combinations thereof.

25. The edge-emitting light emitting diode of claim 1, wherein at least one of said first and second carrier confinement layers comprises a superlattice structure, wherein said superlattice structure comprises plurality of layers of aluminum gallium nitride based material.

26. The edge-emitting light emitting diode of claim 24, wherein said plurality of layers of aluminum gallium nitride based material have alternating high and low concentration of aluminum.

27. The edge-emitting light emitting diode of claim 1, wherein said diode emits radiation in a wavelength range of from about 220 nanometers to about 370 nanometers.

28. An edge-emitting light emitting diode, comprising:
a contact layer;
a first carrier confinement layer coupled to said contact layer, wherein said carrier confinement layer comprises an aluminum gallium nitride based material;
an active region optically coupled to said first carrier confinement layer, wherein said active region comprises an indium gallium nitride or gallium nitride based material;
a second carrier confinement layer optically coupled to said active region, wherein said second carrier confinement layer comprises an aluminum gallium nitride based material, wherein said second carrier confinement layer is n-doped;
a cladding layer optically coupled to said second carrier confinement layer, wherein said cladding layer comprises an aluminum gallium nitride based material, and wherein said cladding layer is either n-doped or undoped;
a buffer layer coupled to said cladding layer; and
a substrate coupled to said buffer layer.

29. The edge-emitting light emitting diode of claim 27, wherein at least one of said first carrier confinement layer, said second carrier confinement layer and said cladding layer comprises a superlattice structure, wherein said superlattice structure comprises plurality of layers of gallium nitride or aluminum gallium nitride based material.

30. The edge-emitting light emitting diode of claim 27, wherein said diode emits radiation in a wavelength range of from about 370 nanometers to about 780 nanometers.

31. A system, comprising:
an edge-emitting light emitting diode, comprising:
a contact layer;
a first carrier confinement layer coupled to said contact layer;
an active region optically coupled to said first carrier confinement layer, said active region comprising an aluminum gallium nitride based material;
a second carrier confinement layer optically coupled to said active region; and
an electronic device disposed adjacent to said edge-emitting light emitting diode such that the radiation from said edge-emitting light emitting diode is received by said electronic device.

32. The system of claim 30, further comprising feedback circuitry coupled to a photodetector and said edge-emitting light emitting diode, wherein said feedback circuitry is configured to alter a driving power of said edge-emitting light emitting diode to maintain a predetermined radiance for said edge-emitting light emitting diode.

33. The system of claim 30, wherein said electronic device is coupled to said edge-emitting light emitting diode through an optical fiber.

34. The system of claim 30, wherein said edge-emitting light emitting diode emits radiation in an ultraviolet region, and wherein said electronic device is a photodetector configured to detect radiation in ultraviolet region.

35. The system of claim 30, wherein said system comprises a biochemical sensor, a water purification device, an air purification device, a polymer curing device, a chemical processing device, a therapeutic device, a solid-state lighting device, a non-line-of-sight communication device, a high-density data storage device, or combinations thereof.

36. The system of claim 30, wherein said electronic device is monolithically integrated with said edge-emitting light emitting diode.
